(19) United States
(12) Patent Application Publication
(10) Pub. No.: US 2026/0065958 A1
(43) Pub. Date: Mar. 5, 2026

(54) SENSING AMPLIFIER DEVICE, MEMORY SENSING METHOD AND MEMORY DEVICE

(71) Applicant: MACRONIX INTERNATIONAL CO., LTD., HSINCHU (TW)

(72) Inventors: Chun-Hao TSAI, Taoyuan City (TW); Shang-Chi YANG, Changhua County (TW); Chun-Hsiung HUNG, Hsinchu City (TW)

(21) Appl. No.: 18/815,971

(22) Filed: Aug. 27, 2024

(51) Int. Cl. G11C 7/06; G11C 7/10; G11C 7/14

(52) U.S. Cl. CPC G11C 7/062; G11C 7/1069; G11C 7/14

(57) ABSTRACT

A sensing amplifier device, comprising a sensing amplifier circuit, a reference transistor and a current compensation circuit. The sensing amplifier circuit generates a sensing signal according to a voltage difference between a first input terminal and a second input terminal. The first input terminal is coupled to a memory cell configured to form a cell current. The reference transistor forms a reference current, so that the sensing amplifier circuit forms a reference voltage at the second input terminal. The current compensation circuit is coupled to the first input terminal and the memory cell. When the sensing amplifier circuit starts to sense, the current compensation circuit is turned on to form a compensation current. The sensing amplifier circuit forms a sensing voltage at the first input terminal according to the compensation current and the cell current.

### BACKGROUND

### Technical Field

The present disclosure relates to memory technology, particularly a sensing amplifier device, a memory sensing method and a memory device.

### Description of Related Art

With the development of memory technology, the density of memory cells has become higher and higher, and the data content that can be stored has also increased accordingly. However, the reading circuit and reading method in the memory device need to be adjusted accordingly in order for the memory device to perform as expected.

### SUMMARY

One aspect of the present disclosure is a sensing amplifier device, comprising a sensing amplifier circuit, a reference transistor and a current compensation circuit. The sensing amplifier circuit comprises a first input terminal and a second input terminal, and is configured to generate a sensing signal according to a voltage difference between the first input terminal and the second input terminal. The first input terminal is coupled to a memory cell, and the memory cell is configured to form a cell current according to a word line signal and a bit line signal. The reference transistor is coupled to the second input terminal and configured to form a reference current according to a reference signal. The sensing amplifier circuit forms a reference voltage at the second input terminal according to the reference current. The current compensation circuit is coupled to the first input terminal and the memory cell, and comprises a switching transistor. When the sensing amplifier circuit starts to sense, the current compensation circuit is configured to turne on the switching transistor to form a compensation current. The sensing amplifier circuit forms a sensing voltage at the first input terminal according to the compensation current and the cell current.

Another aspect of the present disclosure is a memory sensing method, comprising: providing a sensing amplifier circuit, wherein the sensing amplifier circuit comprises a first input terminal and a second input terminal, the first input terminal is coupled to a memory cell, and the second input terminal is coupled to a reference transistor; turning on the reference transistor according to a reference signal to form a reference current, wherein the reference current is configured to form a reference voltage at the second input terminal; turning on the memory cell according to a word line signal and a bit line signal to form a cell current; turning to a current compensation circuit to form a compensation current, wherein the current compensation circuit is coupled to the first input terminal, and the cell current and the compensation current form a sensing voltage at the first input terminal; and generating a sensing signal according to a voltage difference between the sensing voltage and the reference voltage.

Another aspect of the present disclosure is a memory device, comprising a memory cell array, a sensing amplifier circuit, a reference transistor and a current compensation circuit. The memory cell array comprises a plurality of memory cells. The sensing amplifier circuit comprises a first input terminal and a second input terminal, and is configured to generate a sensing signal according to a voltage difference between the first input terminal and the second input terminal. The first input terminal is coupled to the memory cell array. The reference transistor is coupled to the second input terminal and configured to form a reference current according to a reference signal. The sensing amplifier circuit forms a reference voltage at the second input terminal according to the reference current. The current compensation circuit is coupled to the first input terminal and the memory cell array. When the sensing amplifier circuit starts to sense, the current compensation circuit is configured to provide a compensation current, and the memory cell is configured to form a cell current according to a word line signal and a bit line signal. The sensing amplifier circuit forms a sensing voltage at the first input terminal according to the compensation current and the cell current.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic diagram of a memory device in some embodiments of the present disclosure.

FIG. 2 is a schematic diagram of currents of the memory device in some embodiments of the present disclosure.

FIG. 3 is a schematic diagram of a sensing amplifier device in some embodiments of the present disclosure.

FIG. 4 is a flowchart illustrating a memory sensing method in some embodiments of the present disclosure.

FIGS. 5A and 5B are schematic diagrams of signals of the sensing amplifier device in some embodiments of the present disclosure.

### DETAILED DESCRIPTION

For the embodiment below is described in detail with the accompanying drawings, embodiments are not provided to limit the scope of the present disclosure. Moreover, the operation of the described structure is not for limiting the order of implementation. Any device with equivalent functions that is produced from a structure formed by a recombination of elements is all covered by the scope of the present disclosure. Drawings are for the purpose of illustration only, and not plotted in accordance with the original size.

It will be understood that when an element is referred to as being “connected to” or “coupled to”, it can be directly connected or coupled to the other element or intervening elements may be present. In contrast, when an element to another element is referred to as being “directly connected” or “directly coupled,” there are no intervening elements present. As used herein, the term “and/or” includes an associated listed items or any and all combinations of more.

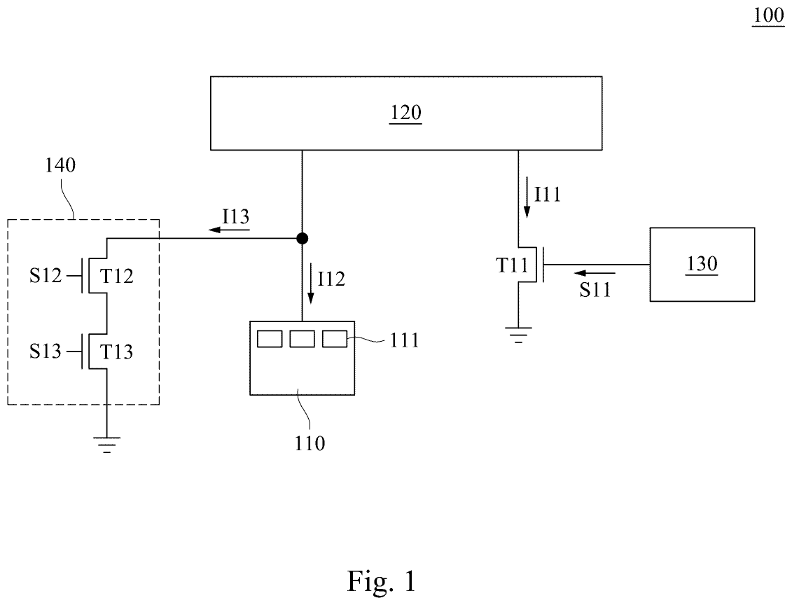

FIG. 1 is a schematic diagram of a memory device 100 in some embodiments of the present disclosure. The memory device 100 can be applied to a Random-Access Memory, such as NOR flash memory or Resistive Random Access Memory (RRAM), but the present disclosure is not limited to this.

The memory device 100 includes a memory cell array 110, a sensing amplifier circuit 120, a reference control circuit 130 and a reference transistor T11. The sensing amplifier circuit 120, the reference control circuit 130 and the reference transistor T11 can be used to a reading circuit of the memory device 100. The memory cell array 110 includes multiple memory cells 111 to store data. The reference control circuit 130 is configured to provide a reference signal S11 to turn on the reference transistor T11 and to form a reference current I11.

Specifically, when the sensing amplifier circuit 120 starts to sense (e.g., read a specific memory cell 111 in the memory cell array 110), the memory device 100 turns on the corresponding memory cell 111 through a corresponding bit line and a corresponding word line, and turns on the reference transistor T11 by the sensing amplifier circuit 120 and the reference control circuit 130 at the same time. At this time, the turned-on memory cell 111 forms a cell current I12, and the turned-on reference transistor T11 forms a reference current I11. The sensing amplifier circuit 120 receives the cell current I12 and the reference current I11 through different input terminals, so as to output a sensing signal according to a relative relationship between the cell current I12 and the reference current I11 (e.g., comparing the magnitude of the two), so that the memory device 100 (e.g., a processor in the memory device 100) can determine whether the data stored in the memory cell 111 is “0” or “1”.

In this embodiment, the memory device 100 further includes a current compensation circuit 140. The current compensation circuit 140 is configured to additionally form a compensation current I13 to the sensing amplifier circuit 120 when the memory cell 111 is turned on (i.e., when the sensing amplifier circuit 120 starts to sense). The compensation current I13 and the cell current I12 converge on the same current path, so the sensing amplifier circuit 120 can compare “the sum of the compensation current I13 and the cell current I12” with the reference current I11. The memory device 100 accordingly determines whether the data stored in the memory cell 111 is “0” or “1”. In other words, the memory device 100 can ensure the accuracy of reading by the current compensation circuit 140.

In one embodiment, the current compensation circuit 140 includes a switching transistor T12 and a compensation transistor T13. The switching transistor T12 is turned on according to the switching signal S12, so as to control the turned-on/off state of the current compensation circuit 140. The compensation transistor T13 is turned on according to the compensation signal S13, so as to control the magnitude of the compensation current I13. The operation of the current compensation circuit 140 will be described in detail in subsequent embodiments.

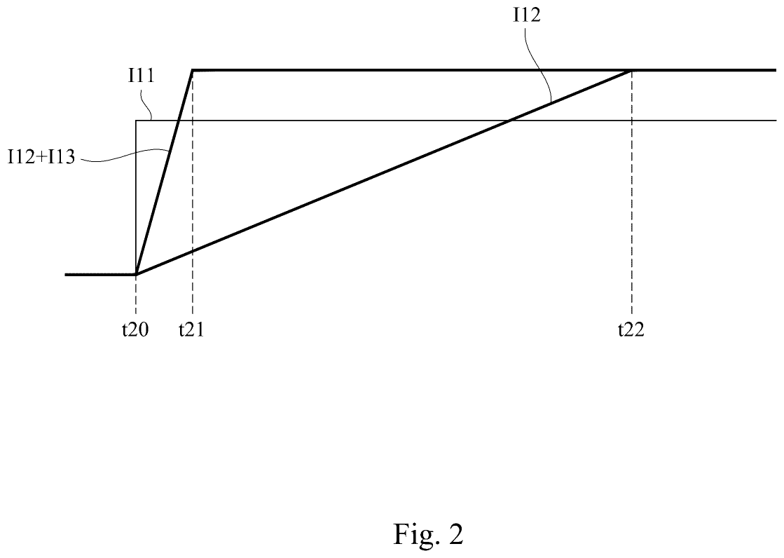

FIG. 2 is a schematic diagram of currents of the memory device 100 in some embodiments of the present disclosure. Here taking FIG. 1 and FIG. 2 as examples to illustrate the application purpose of the current compensation circuit 140. In one embodiment, the reference transistor T11 operates in the saturation mode. When the reference control circuit 130 provides the reference signal S11 to the control terminal of the reference transistor T11, the reference transistor T11 is turned on to generate the reference current I11 (e.g., 6 microamps).

On the other hand, the memory cell 111 (or an internal transistor) operates in linear mode. When the memory cell 111 is turned on according to a word line signal, the magnitude of the formed cell current I12 (or the voltage caused by the cell current) can be used to identify the stored data. For example, when the cell current I12 is less than the reference current I11, it represents a bit “0” (e.g., 4 microamps). When the cell current I12 is greater than the reference current I11, it represents bit “1” (e.g., 8 microamps).

However, in the case of the memory cell array 110 having high density of memory cells, bit lines and word lines in the memory device 100 will charge slower due to a high load condition, and it will take a longer time for the cell current I12 to rise to an expected current value. Therefore, without the current compensation circuit 140, the sensing signal generated by the sensing amplifier circuit 120 at the time t21 may not be correct.

As shown in FIG. 2, the memory device 100 starts to receive the specific memory cell 111 at the time t20. At the same time, the sensing amplifier circuit 120 and the reference control circuit 130 turns on the reference transistor T11, so that the sensing amplifier circuit 120 starts sensing. At the time t21, the memory device 100 determines the data stored by the memory cell 111 according to the sensing signal output by the sensing amplifier circuit 120, so as to determine the data stored by the memory cell 111. However, since the bit line and the word line have not been fully charged at this time, the cell current I12 formed by the memory cell 111 is low, and the sensing signal output by the sensing amplifier circuit 120 may not correctly represent data stored by the memory cell 111. For example, the reference current I11 is 6 microamps, but the cell current I12 is only 0.5 microamps at the time t21, and will rise to more than 6 microamps (e.g., 8 microamps) at the time t22. Therefore, at the time t21, since the cell current I12 is still less than the reference current I11, the sensing signal output by the sensing amplifier circuit 120 will be wrong.

In the case where the current compensation circuit 140 is provided, the current compensation circuit 140 will be turned on at the time t20 to form the compensation current I13. The compensation current I13 and the cell current I12 are on the same current path (i.e., flowing through the same input terminal). Therefore, the compensation current I13 operates like accelerating the cell current I12, so as to ensure that the memory device 100 does not cause errors when reading due to the slower charging speed of the bit line and the word line. As shown in FIG. 2, the compensation current I13 combined with the cell current I12 can rise to the expected 8 microamps at the time t21.

In one embodiment, a turned-on time of the current compensation circuit 140 can be customizable. For example, turning on a preset compensation time to provide the compensation current I13 within the compensation time. In some other embodiments, the turned-on time of the current compensation circuit 140 can be determined according to a voltage on the word line before the sensing amplifier circuit 120 starts sensing the currently selected address in the memory cell array 110 (i.e., time t20). For example, determining whether the word line has a high voltage before starting to charge or determining whether charging of the word line is completed according to the currently selected address. If the word line already has a high voltage, or the currently selected address does not need to be recharged to switch character lines, the turned-on time of the current compensation circuit 140 can be shorter, and it does not even need to be turned on.

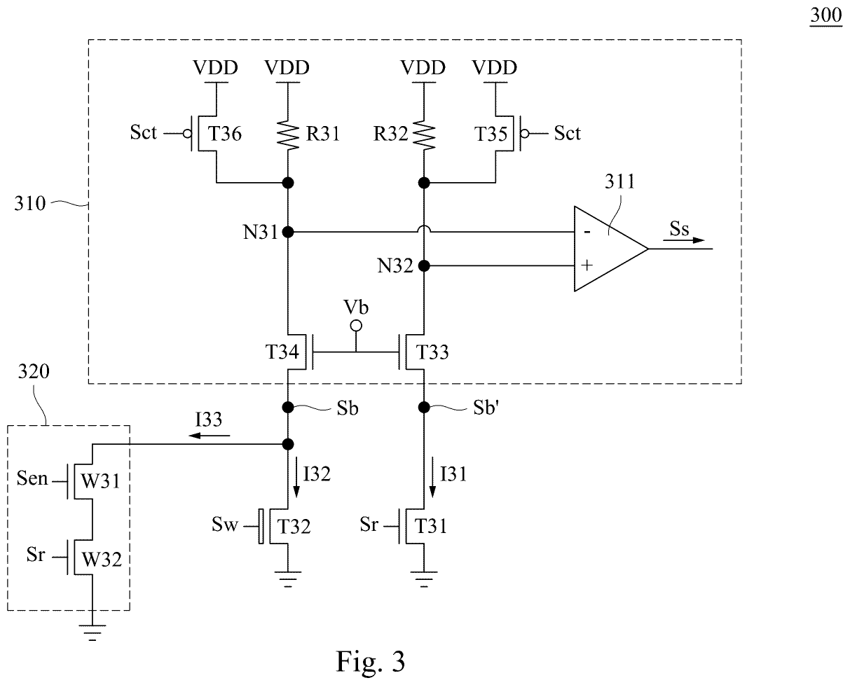

FIG. 3 is a schematic diagram of a sensing amplifier device 300 in some embodiments of the present disclosure. The sensing amplifier device 300 may be used to implement a part of the memory device 100 shown in FIG. 1. The sensing amplifier device 300 is coupled to the memory cell array (not shown in FIG. 3, can be the memory cell array 110 of FIG. 1), and is configured to compare the reference current I31 with the cell current I32 of the specific memory cell to generate the sensing signal Ss, so that the memory device accordingly determine the data stored in the memory cell.

The sensing amplifier device 300 includes a sensing amplifier circuit 310, a reference transistor T31 and a current compensation circuit 320. The sensing amplifier circuit 310 is coupled to a supply voltage VDD as an operation voltage. The sensing amplifier circuit 310 includes a first input terminal N31 (e.g., inverting input) and a second input terminal N32 (e.g., non-inverting input), and is configured to generate the sensing signal Ss according to a voltage difference between the first input terminal N31 and the second input terminal N32.

The first input terminal N31 of the sensing amplifier device 300 is coupled to one or more memory cells in the memory cell array. In one embodiment, the sensing amplifier device 300 can be coupled to multiple memory cells through a multiplexer to sense different memory cells respectively. Since those skilled in the art can understand composition of the memory cell and a connection with the sensing amplifier device 300, they are not further detailed herein. In addition, FIG. 3 shows a cell transistor in a memory cell to represent the memory cell.

The memory cell T32 is configured to form the cell current I32 according to a word line signal Sw and a bit line signal Sb. Specifically, the control terminal of the memory cell T32 is coupled to the word line to receive the word line signal Sw, so that the memory cell T32 is turned on or off according to the word line signal Sw. A terminal of the memory cell T32 is coupled to the bit line to receive a bit voltage provided by the bit line (i.e., the bit line signal Sb shown in FIG. 3).

The reference transistor T31 is coupled to the second input terminal N32, and is configured to generate the reference current I31 according to the reference signal Sr. Specifically, the control terminal of the reference transistor T31 is configured to receive a reference signal Sr (e.g., provided by the reference control circuit 130 shown in FIG. 1), so that the reference transistor T31 is turned on or off according to the reference signal Sr. A terminal of the reference transistor T31 is coupled to a reference line to receive a reference bit line signal Sb′ provided by the reference line. In one embodiment, the reference bit line signal Sb′ is same as bit voltage (the bit line signal Sb) provided by the bit line.

The current compensation circuit 320 is coupled to the first input terminal N31 and a terminal of the memory cell T32, and includes a switching transistor W31. When the sensing amplifier device 300 starts to perform a sensing process, the current compensation circuit 320 turns on the switching transistor W31, so that a current path between the current compensation circuit 320, the first input terminal N31 and the supply voltage VDD is formed, and the compensation current I33 is generated.

The sensing amplifier circuit 310 is configured to compare “sum of the cell current I32 and the compensation current I33” and the reference current I31 to generate the sensing signal Ss. In one embodiment, the sensing amplifier circuit 310 is configured to form a sensing voltage at the first input terminal N31 according to the sum of the cell current I32 and the compensation current I33, and is configured to form a reference voltage at the second input terminal N32 according to the reference current I31. Accordingly, the sensing signal Ss is generated by a relative voltage relationship between the first input terminal N31 and the second input terminal N32.

Specifically, as shown in FIG. 3, the sensing amplifier circuit 310 further includes an amplifier 311, a first impedance element R31 and a second impedance element R32. The amplifier 311 can be a comparison circuit, and the input terminals are the first input terminal N31 and the second input terminal N32. The first impedance element R31 is coupled to the first input terminal N31, the cell current I32 and the compensation current I33 flow through the first input terminal N31, so that the first impedance element R31 forms the sensing voltage at the first input terminal N31 according to the cell current I32 and the compensation current I33.

Similarly, the second impedance element R32 is coupled to the second input terminal N32, and the reference current I31 flows through the second impedance element R32, so that the second impedance element R32 forms the reference voltage on the second input terminal N32 according to the reference current I31.

When the sensing voltage at the first input terminal N31 is less than the reference voltage at the second input terminal N32, the sensing signal Ss output by the sensing amplifier circuit 310 is a high level, which means that the read data is bit “1”. When the sensing voltage at the first input terminal N31 is greater than the reference voltage at the second input terminal N32, the sensing signal Ss output by the sensing amplifier circuit 310 is a low level, which means that the read data is bit “0”.

In one embodiment, the sensing amplifier circuit 310 is coupled to the reference transistor T31 and the memory cell T32 respectively through the bit clamp transistors T33 and T34. Control terminals of the bit clamp transistors T33 and T34 respectively control the reference bit line signal Sb′ and the bit line signal Sb according to a bias voltage Vb.

In one embodiment, the sensing amplifier circuit 310 further includes word charging transistors T35, T36. The word charging transistors T35, T36 are respectively coupled to the second input terminal N32 and the first input terminal N31 of the amplifier 311. After the reference transistor T31 and the memory cell T32 are turned on by the reference signal Sr and the word line signal Sw respectively, word charging transistors T35, T36 are turned on according to the bit charging signal Sct to provide a reading voltage (i.e., the above bit voltage/bit line signal Sb and the reference bit line signal Sb′) through the supply voltage VDD.

In one embodiment, the switching transistor W31 is turned on according to the switching signal Sen. A supply time of the switching control signal Sen may depend on the charging time of the word line. For example, determining whether the voltage of the word line has been fully charged before the sensing amplifier circuit 310 starts to sense according to the currently selected address. In addition, in some embodiments, the current compensation circuit 320 further includes a compensation transistor W32. The compensation transistor W32 is coupled in series to the switching transistor W31, and is turned on according to the compensation signal Sr to control the magnitude of the compensation current I33.

As mentioned above, in the embodiment shown in FIG. 3, the current compensation circuit 320 controls the magnitude of the compensation current by the compensation transistor W32, but the present disclosure is not limited to this. In some other embodiments, the compensation transistor W32 can be replaced with a compensation capacitor. The compensation capacitor is coupled in series to the switching transistor W31. When the switching transistor W31 is turned on, a charging path is formed between the current compensation circuit 320, the first input terminal N31 and the supply voltage VDD to charge the compensation capacitor and form the compensation current I33.

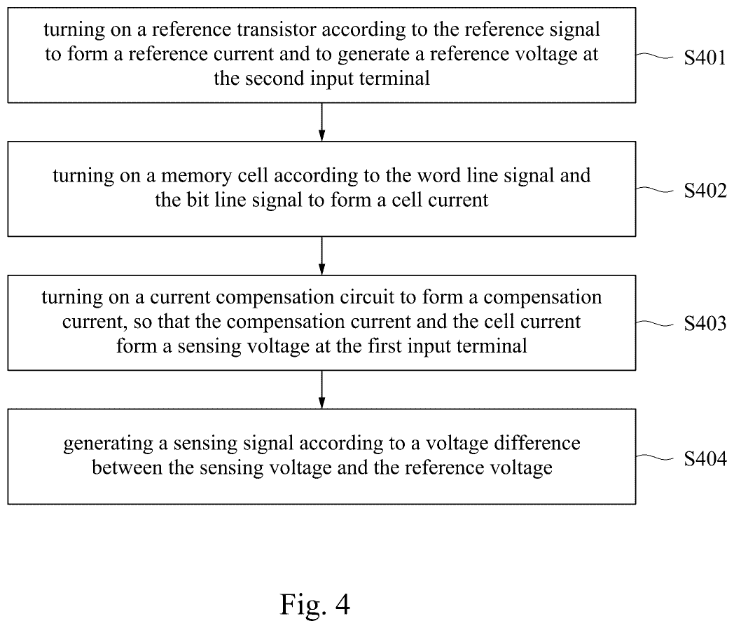

For ease of understanding, the following description is according to the memory sensing method shown in FIG. 4. The memory sensing method is applied to the sensing amplifier device 300 shown in FIG. 3, but can also be applied to the memory device 100 shown in FIG. 1. The memory sensing method includes steps S401-S404 shown in FIG. 4.

In step S401, when the sensing amplifier circuit 310 starts to sense the memory cell T32, the sensing amplifier device 300 generates a reference signal Sr to turn on the reference transistor T31, so that the reference transistor T31 generates a reference current I31, and the reference current I31 forms a reference voltage at the second input terminal N32. As mentioned above, the reference current I31 can form the reference voltage by the second impedance element R32.

In step S402, the memory device transmits a bit line signal Sb and a word line signal Sw to the corresponding memory cell T32 through the bit line and the word line to turn on the memory cell T32. After the memory cell T32 is turned on, the cell current I32 will be formed. Since the bit line and the word line are coupled to the multiple memory cells of the memory cell array, under a high load condition, voltage signal provided by the bit line and the word line takes a while to charge to the expected value. In other words, the bit line signal Sb and the word line signal Sw gradually increase to the expected value over time.

In one embodiment, the memory cell T32 can be turned on according to the word line signal Sw first, and then receive the bit line signal Sb (e.g., turn on the word charging transistor T36) to generate the cell current I32. In other words, the present disclosure does not limit the word line signal Sw and the bit line signal Sb to be provided at the same time. Similarly, the reference transistor T31 can be turned on by the reference signal Sr first, and then receive the reference bit line signal Sb′ to generate the reference current I31.

In step S403, the current compensation circuit 320 is connected to the first input terminal N31 to form the compensation current I33. The compensation current I33 and the cell current I32 both flow through the first impedance element R31 to form the sensing voltage at the first input terminal N31. As mentioned above, the compensation current I33 and the cell current I32 form the sensing voltage by the first impedance element R31. In one embodiment, the turned-on time of the current compensation circuit 320 may be the time when the sensing amplifier circuit 310 starts sensing.

In step S404, after receiving the sensing voltage and the reference voltage, the sensing amplifier circuit 310 generates the sensing signal Ss according to a voltage difference between the sensing voltage of the first input terminal N31 and the reference voltage of the second input terminal N32. For example, if the sensing voltage is less than the reference voltage, the output sensing signal Ss is a high level, representing bit “1”. If the sensing voltage is greater than the reference voltage, the output sensing signal Ss is a low level, representing the bit “0”.

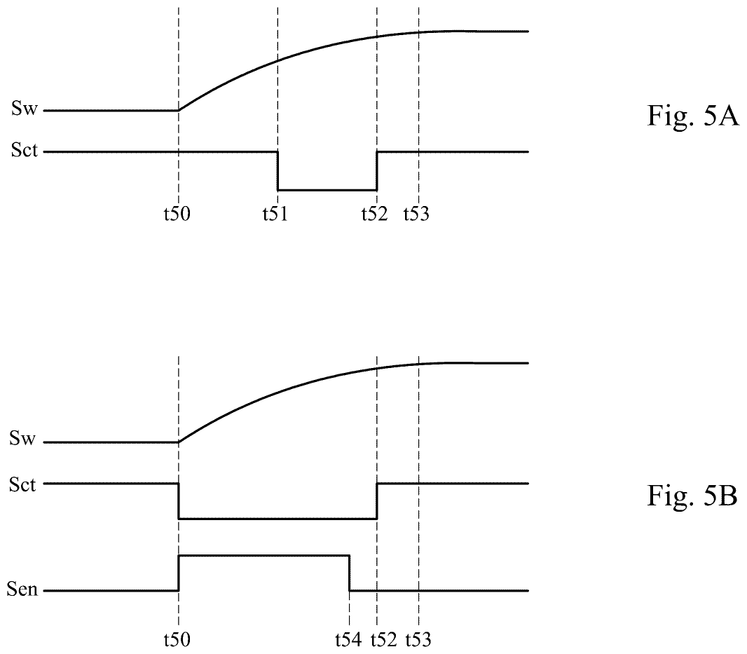

FIGS. 5A and 5B are schematic diagrams of signals of the sensing amplifier device in some embodiments of the present disclosure. FIG. 5A is a signal schematic diagram of the sensing amplifier device 300 without the current compensation circuit 320. FIG. 5B is a signal schematic diagram of the sensing amplifier device 300 with the current compensation circuit 320.

As shown in FIG. 5A, at the time t50, the word line starts charging, the memory cell T32 receives the word line signal Sw, and the reference transistor receives the reference signal Sr.

At the time t51, the word line signal Sw should ideally be charged to an expected voltage. At this time, the sensing amplifier device 300 starts to sense, and the bit line starts charging until the time t52 (e.g., turns on the word charging transistors T35, T36 by the bit charging signal Sct) to provide the bit line signal Sb to the memory cell T32. At the same time, the reference transistor T31 receives the reference bit line signal Sb′. The turned-on reference transistor T31 and the memory cell T32 respectively form the reference current I31 and the cell current I32.

A time from time t52 to time t53 is a time for the first input terminal N31 and the second input terminal N32 to establish the sensing voltages according to the currents flowing through them. At the time 53, the sensing amplifier circuit 310 outputs the sensing signal Ss according to a voltage difference between the first input terminal N31 and the second input terminal N32, so that the processor of the memory device determines whether the memory cell stores bit “1” or “0”.

Since the embodiment of FIG. 5A does not use the current compensation circuit 320, when the bit line and the word line have high loads due to the high density of the memory cells, the charging speed of the word line and the bit line will be slower. In addition, when high read speed is required, the memory device usually needs to complete the reading process at the time t53, so the read result may be wrong.

As shown in FIG. 5B, in the embodiment with the current compensation circuit 320, the current compensation circuit 320 is turned on at the time t50. That is, the switching signal Sen is enabled at the time t50, and a time from time t50 to time t54 is a compensation time. The compensation current I33 is configured to compensate for the problem that the current flowing through the first impedance element R31 cannot rise to the expected value at the time t51 due to the charging speed of the word line being too slow. Therefore, the bit line can start charging in advance at the time t50 (e.g., turns on the word charging transistors T35, T36 by the bit charging Sct) to provide the bit line signal Sb to the memory cell T32, so there is no need to worry about overcharging due to insufficient current. In other words, when the switching transistor W31 is turned on to generate the compensation current I33, the memory cell T32 can start to receive the bit line signal Sb. Accordingly, the bit line can have more ample charging time.

The aforementioned control method uniformly increases the total current flowing through the first input terminal N31 by the compensation current I33. Accordingly, the problem of too small read margin or reading errors caused by the word line or the bit line charging speed being too slow can be avoided. For example, the reference current is 6 microamps, so when the current of the first input terminal N31 is less than 6 microamps, the output sensing signal Ss is a low level, representing the bit “0”. When the current of the first input terminal N31 is greater than 6 microamps, the output sensing signal Ss is a high level, representing the bit “1”.

As mentioned above, in the embodiment without the current compensation circuit 320, when the memory cell is bit “0”, the current read out may be 3 microamps. When the memory cell is bit “1”, the current read out may be 7 microamps. Since 7 microamps is too close to 6 microamps, it is possible reading errors due to error or interference.

On the other hand, in the embodiment with the current compensation circuit 320, because the compensation current I33 is used, no matter what data is stored in the memory cell, the current of the first input terminal N31 will be increased. When the memory cell is bit “0”, the current read out may be 4 microamps. When the memory cell is bit “1”, the current read out may be 8 microamps. Accordingly, whether data is bit “1” or “0”, the voltage/current between the first input terminal N31 and the second input terminal N32 is significantly different enough to avoid reading errors.

As mentioned above, the switching transistor W31 (equal to the switching transistor T12 in FIG. 1) of the current compensation circuit 320 is turned on according to the switching signal Sen, and the supply time of the switching signal Sen is a preset compensation time to provide the compensation current I33 within the compensation time. In some other embodiments, the compensation time is inversely related to an initial voltage, which is a voltage value before the word line signal turns on the memory cell T32. This “initial voltage” can be a voltage value of the word line before (or at the beginning) the sensing amplifier device 300 performs the sensing process on the specific memory cell, or can be a voltage value maintained by the word line (the word line signal Sw) after turning on the previous one of the memory cells. In other words, the memory device 100 determines whether the initial voltage of the word line signal Sw has been fully charged before the sensing amplifier device 300 starts to sense according to the currently selected address, and the compensation time is determined by the time when the word line charging is completed.

Specifically, referring to FIG. 3, the sensing amplifier device 300 is configured to sense multiple memory cells. Therefore, when the sensing amplifier circuit 310 starts to sense, the sensing amplifier device 300 is connected to different memory cells sequentially according to a driving sequence of the word line for sensing. If the word line has been charged to a high potential (e.g., 7 volts) when sensing the previous one of the memory cells, then when sensing the next memory cell, there is no need to turn on the current compensation circuit 320, because the word line will not have the problem of slow charging.

In other words, in some embodiments, before the sensing amplifier device 300 starts to sense the memory cell T32, the memory device/the sensing amplifier device 300 determine whether the word line signal Sw on the word line is greater than a preset setting value (e.g., 7 volts). For example, the memory device 100 determines whether the currently selected address in the memory cell array 110 needs to be recharged to adjust the word line signal Sw. If the word line signal Sw is already greater than the preset setting value or does not need to be switched, it means that the word line signal Sw is already at high voltage (e.g. 7 volts) and does not need to recharge. At this time, the switching signal Sen is maintain to disable, so as to turn off the current compensation circuit 320. In other words, in this case there is no need to turn on the current compensation circuit 320.

The elements, method steps, or technical features in the foregoing embodiments may be combined with each other, and are not limited to the order of the specification description or the order of the drawings in the present disclosure.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

What is claimed is:

1. A sensing amplifier device, comprising:
a sensing amplifier circuit comprising a first input terminal and a second input terminal, and configured to generate a sensing signal according to a voltage difference between the first input terminal and the second input terminal, wherein the first input terminal is coupled to a memory cell, and the memory cell is configured to form a cell current according to a word line signal and a bit line signal;
a reference transistor coupled to the second input terminal and configured to form a reference current according to a reference signal, wherein the sensing amplifier circuit forms a reference voltage at the second input terminal according to the reference current; and
a current compensation circuit coupled to the first input terminal and the memory cell, and comprising a switching transistor, wherein when the sensing amplifier circuit starts to sense, the current compensation circuit is configured to turn on the switching transistor to form a compensation current;
wherein the sensing amplifier circuit forms a sensing voltage at the first input terminal according to the compensation current and the cell current.

2. The sensing amplifier device of claim 1, wherein the switching transistor is turned on for a compensation time to provide the compensation current within the compensation time.

3. The sensing amplifier device of claim 2, wherein the compensation time is inversely related to an initial voltage, which is a voltage value before the word line signal turns on the memory cell.

4. The sensing amplifier device of claim 1, wherein before the sensing amplifier circuit starts to sense, if the word line signal is greater than a setting value, turning off the current compensation circuit.

5. The sensing amplifier device of claim 1, wherein when the switching transistor is turned on to form the compensation current, the memory cell starts to receive the bit line signal.

6. The sensing amplifier device of claim 1, wherein the current compensation circuit comprises:
a compensation transistor coupled in series to the switching transistor, and turned on according to the reference signal.

7. The sensing amplifier device of claim 1, wherein the current compensation circuit comprises:
a compensation capacitor coupled in series to the switching transistor.

8. The sensing amplifier device of claim 1, wherein the sensing amplifier circuit comprises:
an amplifier comprising the first input terminal and the second input terminal;
a first impedance element coupled to the first input terminal, and configured to form the sensing voltage according to the compensation current and the cell current; and
a second impedance element coupled to the second input terminal, and configured to form the reference voltage according to the reference current.

9. A memory sensing method, comprising:
providing a sensing amplifier circuit, wherein the sensing amplifier circuit comprises a first input terminal and a second input terminal, the first input terminal is coupled to a memory cell, and the second input terminal is coupled to a reference transistor;
turning on the reference transistor according to a reference signal to form a reference current, wherein the reference current is configured to form a reference voltage at the second input terminal;
turning on the memory cell according to a word line signal and a bit line signal to form a cell current;
turning to a current compensation circuit to form a compensation current, wherein the current compensation circuit is coupled to the first input terminal, and the cell current and the compensation current form a sensing voltage at the first input terminal; and
generating a sensing signal according to a voltage difference between the sensing voltage and the reference voltage.

10. The memory sensing method of claim 9, wherein turning to the current compensation circuit comprises:
turning to a switching transistor of the current compensation circuit for a compensation time to provide the compensation current within the compensation time.

11. The memory sensing method of claim 10, wherein the compensation time is inversely related to an initial voltage, which is a voltage value before the word line signal turns on the memory cell.

12. The memory sensing method of claim 9, further comprising:
determining whether an initial voltage of the word line signal is greater than a setting value before the memory cell is turned on according to the word line signal; and
if the initial voltage is greater than the setting value, turning off the current compensation circuit.

13. The memory sensing method of claim 9, wherein turning to the current compensation circuit comprises:
when turning on a switching transistor of the current compensation circuit, starting to receive the bit line signal.

14. The memory sensing method of claim 9, wherein turning to the current compensation circuit to form the compensation current comprises:
turning on a switching transistor of the current compensation circuit, and turning on a compensation transistor of the current compensation circuit according to the reference signal, wherein the compensation transistor is coupled in series to the switching transistor.

15. The memory sensing method of claim 9, wherein turning to the current compensation circuit to form the compensation current comprises:
turning on a switching transistor of the current compensation circuit to charge a compensation capacitor of the current compensation circuit, wherein the compensation capacitor is coupled in series to the switching transistor.

16. The memory sensing method of claim 9, further comprising:
forming, by a first impedance element of the sensing amplifier circuit, the sensing voltage according to the cell current and the compensation current; and
forming, by a second impedance element of the sensing amplifier circuit, the reference voltage according to the reference current.

17. A memory device, comprising:
a memory cell array comprising a plurality of memory cells;
a sensing amplifier circuit comprising a first input terminal and a second input terminal, and configured to generate a sensing signal according to a voltage difference between the first input terminal and the second input terminal, wherein the first input terminal is coupled to the memory cell array;
a reference transistor coupled to the second input terminal and configured to form a reference current according to a reference signal, wherein the sensing amplifier circuit forms a reference voltage at the second input terminal according to the reference current; and
a current compensation circuit coupled to the first input terminal and the memory cell array, wherein when the sensing amplifier circuit starts to sense, the current compensation circuit is configured to provide a compensation current, and the one of the plurality of memory cells is configured to form a cell current according to a word line signal and a bit line signal;
wherein the sensing amplifier circuit forms a sensing voltage at the first input terminal according to the compensation current and the cell current.

18. The memory device of claim 17, wherein the current compensation circuit is configured to turn on a switching transistor for a compensation time to provide the compensation current within the compensation time.

19. The memory device of claim 18, wherein the compensation time is inversely related to an initial voltage, which is a voltage value when the word line signal turns on a previous one of the plurality of memory cells.

20. The memory device of claim 18, wherein if an initial voltage when the word line signal turns on a previous one of the plurality of memory cells is greater than a setting value, turning off the current compensation circuit.
